(19) United States
(12) Patent Application Publication
(10) Pub. No.: US 2024/0180014 A1
(43) Pub. Date: May 30, 2024

(54) METHOD FOR MANUFACTURING PHOTORESPONSIVE ARRAY ELEMENT

(71) Applicant: CANON KABUSHIKI KAISHA, Tokyo (JP)

(72) Inventor: TAKAYUKI TESHIMA, Kanagawa (JP)

(21) Appl. No.: 18/523,659

(22) Filed: Nov. 29, 2023

(30) Foreign Application Priority Data
Nov. 30, 2022 (JP) 2022-190926

(51) Int. Cl. H10K 71/18

(52) U.S. Cl. CPC H10K 71/18

(57) ABSTRACT

A resist layer containing a photoresponsive material in a photoresist is layer-transferred from a film on which the resist layer is formed to a bank substrate, and exposure and development are performed so as to remove an unexposed resist layer.

### BACKGROUND

### Field of the Disclosure

The present disclosure relates to a method for manufacturing a photoresponsive array element.

### Description of the Related Art

In recent years, application of a quantum dot serving as a photoresponsive material to a display element has been investigated. Regarding such a display element including the quantum dot, a display element provided with a color filter including a wavelength conversion layer containing a quantum dot between partition walls on an organic light-emitting pixel array serving as a light source has been proposed.

In the region of each pixel in the color filter including the wavelength conversion layer, wavelength conversion layers containing quantum dots having light emission wavelengths that differ from each other due to wavelength conversion are disposed adjoining each other. Regarding the method for forming a color conversion layer, an ink jet method which is considered to have an advantage in terms of tact time and material costs over the method in which a subpixel is patterned using photolithography in the related art is disclosed. Japanese Patent Laid-Open No. 2022-102056 discloses that the partition wall being provided with high liquid repellency suppresses the film thickness of a light-emitting layer from becoming nonuniform due to an ink including the light-emitting layer coming into contact with or breaching the partition wall. However, when the color filter is produced by the ink jet method, a satellite droplet generated in accordance with a main ink droplet landing on a region in a bank with a different light emission wavelength may cause color mixing.

Japanese Patent Laid-Open No. 2019-113759 discloses that an ink containing a photosensitive composition including a quantum dot is injected in a bank by the ink jet method and that a satellite droplet that has landed on a region in a bank with a different light emission wavelength is removed by photolithography.

However, since a photoresponsive material in a wet state is applied into the bank, as per the methods described in Japanese Patent Laid-Open No. 2022-102056 and Japanese Patent Laid-Open No. 2019-113759, there is a concern that color mixing of light emission of the photoresponsive material may occur due to contamination of other sections by a satellite liquid and due to contamination on the partition wall through wetting and spreading, diffusion, and the like.

In the related art, when the photoresponsive materials having different photoresponsivity are used as an array-like light-emitting element such as a wavelength conversion layer, there is a concern that color mixing of emission colors from adjacent pixels corresponding to adjacent banks may occur, and accordingly, further improvement is desired. When the photoresponsive material is used as the light-emitting material, a photoresponsive array element in which color mixing of emission colors from adjacent pixels corresponding to adjacent banks is decreased may be provided.

### SUMMARY

The present disclosure was realized in consideration of such background technology and provides a method for manufacturing a photoresponsive array element in which a photoresponsive material is disposed so as to remain in a bank.

The present disclosure provides a method for manufacturing a photoresponsive array element including a first step of preparing a bank substrate provided with a partition wall protruding from a substrate to form a plurality of bank portions, a second step of preparing a multilayer film including a resist layer containing a photoresponsive material and a resist material supporting the photoresponsive material and a film supporting the resist layer, and a third step of bringing the multilayer film into contact with the bank substrate to apply pressure from the partition wall to the resist layer and thereafter moving the film away from the bank substrate.

Further features of the present disclosure will become apparent from the following description of exemplary embodiments with reference to the attached drawings.

### BRIEF DESCRIPTION OF THE DRAWINGS

FIG. 1 is a flow chart illustrating a manufacturing method according to an embodiment.

FIG. 2A is a flow chart illustrating a manufacturing method according to a first embodiment, FIG. 2B(2b-1) to FIG. 2B(2b-5) are step diagrams illustrating the manufacturing method according to the first embodiment, FIG. 2C is a flow chart illustrating a manufacturing method according to a modified form of the first embodiment, and FIG. 2D is a sectional view illustrating a photoresponsive array element.

FIG. 3A is a flow chart illustrating a first step according to the first embodiment, and FIG. 3B(3b-1) to FIG. 3B(3b-3) are step diagrams illustrating the first step according to the first embodiment.

FIG. 4 is a flow chart according to a second embodiment.

### DESCRIPTION OF THE EMBODIMENTS

The preferred embodiments of the present disclosure will be described below in detail with reference to the attached drawings. In this regard, in the drawings, the same members are indicated by the same references, and duplicate explanations may be omitted.

The embodiments will be described below in further detail.

A method for manufacturing a photoresponsive array element according to the embodiment of the present disclosure includes the following steps.
(1) A first step of preparing a bank substrate provided with a partition wall protruding from a substrate to form a plurality of bank portions.
(2) A second step of preparing a multilayer film including a resist layer containing a photoresponsive material and a resist material supporting the photoresponsive material and a film supporting the resist layer.
(3) A third step of bringing the multilayer film into contact with the bank substrate to apply pressure from the partition wall to the resist layer and thereafter moving the film away from the bank substrate.

The embodiments according to the present disclosure will be described below with reference to the drawings.

### First Embodiment

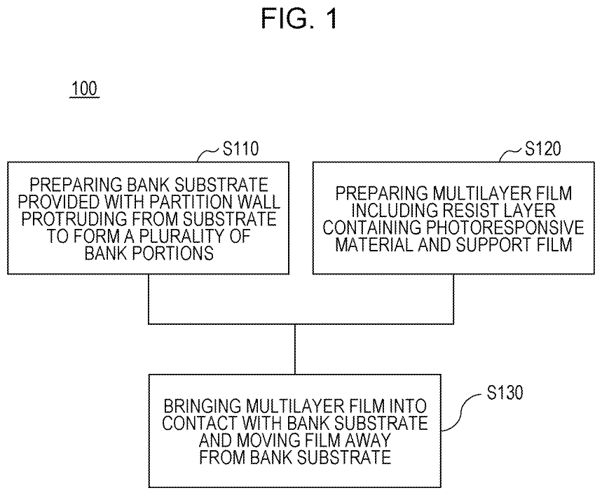

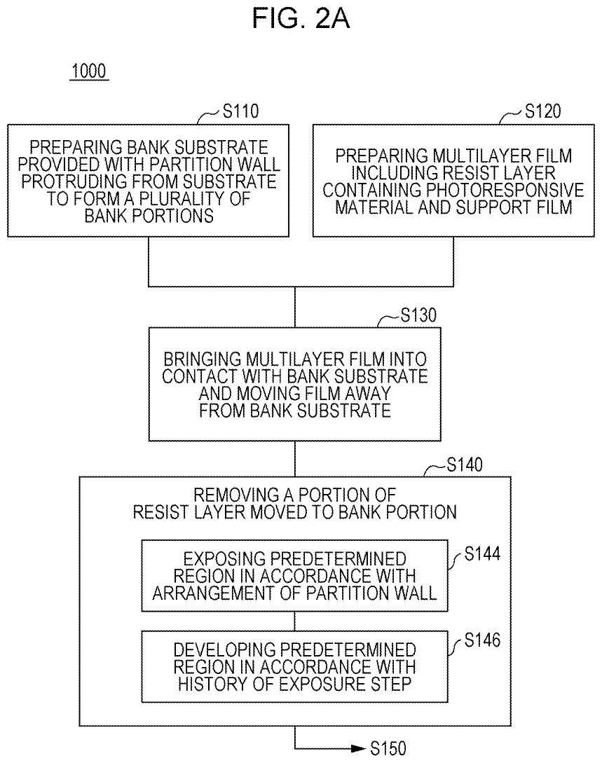

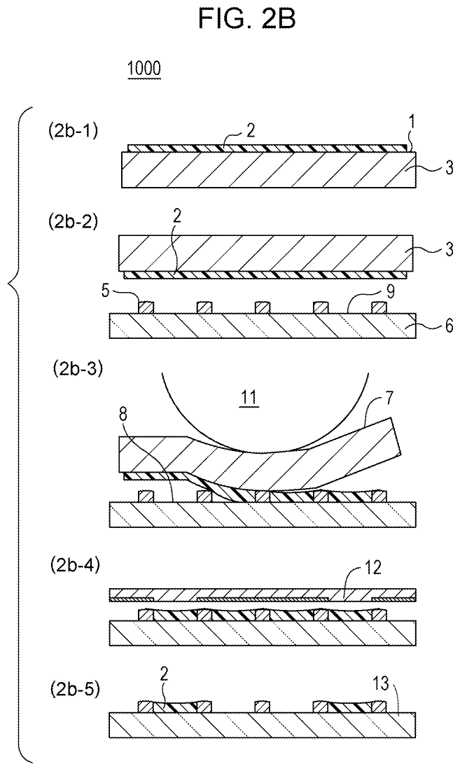

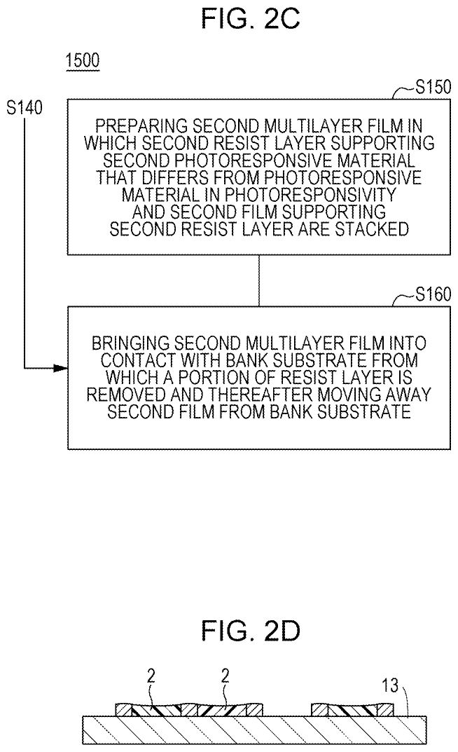

In the present embodiment, a manufacturing method 1000 of a photoresponsive array element 3000 will be described with reference to FIG. 1 and FIG. 2A to FIG. 2D.

### First Step

The first step corresponds to Step S110 in FIG. 1 and FIG. 2A. In addition, the first step (Step S110) corresponds to the formation step of forming a bank substrate 6 illustrated in a lower portion of FIG. 2B(2b-2). In this regard, FIG. 1 is a flow chart illustrating the manufacturing method according to a basic embodiment common to the first embodiment and the second embodiment, and FIG. 2A to FIG. 2B(2b-5) are flow charts illustrating the manufacturing method 1000 according to the present embodiment.

The first step is a step of preparing a bank substrate 6 provided with a partition wall 5 protruding from the substrate to form a plurality of bank portions 9. Regarding the partition wall 5, a material having a hardness which enables a resist layer 2 described later to be subjected to plastic deformation due to application of pressure to the resist layer 2 is adopted. Plastic deformation of the resist layer 2 includes cutting and a layer thickness reduction. The substrate supporting a plurality of partition walls 5 has a higher hardness than the resist layer 2 to effectively apply a pressurization force to the resist layer 2 during the second step (Step S120) of subjecting the resist layer 2 to the plastic deformation due to the partition wall 5. Therefore, regarding each of the substrate and the partition wall 5 of the bank substrate 6, a material having a higher modulus of elasticity than the resist layer 2 described later is adopted.

### Second Step

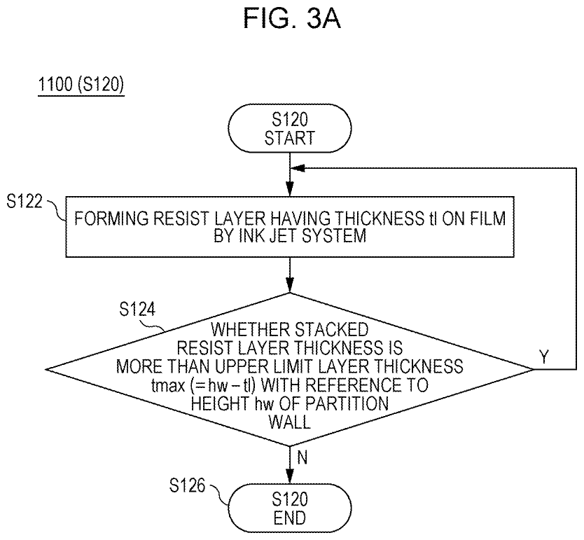

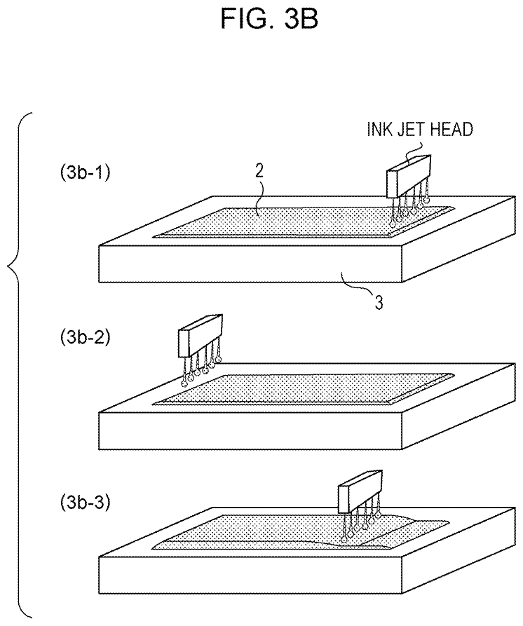

The second step corresponds to Step S120 in FIG. 1, FIG. 2A, and FIG. 3B(3b-1). In addition, the second step (Step S120) corresponds to the formation step of forming a multilayer film illustrated in FIG. 2B(2b-1).

As illustrated in FIG. 2B(2b-1), the multilayer film including the resist layer 2 and a film 3 supporting the resist layer 2 is prepared.

Regarding the film 3 used in the present embodiment, plastic such as polyethylene terephthalate (PET), polyethylene naphthalate (PEN), polyvinyl chloride (PVC), polypropylene (PP), polycarbonate (PC), polyethylene (PE), polyurethane (PU), polyimide (PI), and polyvinyl alcohol (PVA) may be used. The thickness of the base material can be minimized within the bounds of the base material not breaking under the use condition and is preferably 1,000 μm or less, more preferably 500 μm or less, and further preferably 100 μm or less. Examples of usable commercially available film include ICROS tape (produced by Mitsui Chemicals, Inc.), ELEP HOLDER (produced by NITTO DENKO CORPORATION), Semiconductor UV tape (produced by Furukawa Electric Co., Ltd.), Adwill (produced by LINTEC Corporation), ELEGRIP TAPE (produced by Denka Company Limited), SUMILITE (produced by Sumitomo Bakelite Co., Ltd.), and ST Chuck Tape (produced by ACHILLES CORPORATION). In this regard, the film having lower adhesiveness to the photoresist described later than the bank bottom surface and the partition wall being selected improves the layer-transferability of the resist layer.

The photoresist used in the present embodiment is a photoresist used in a common semiconductor process and is a photoresist that exhibits a difference in solubility in a developing solution between an exposed portion and an unexposed portion. Either a positive resist or a negative resist may be used, and the negative resist having favorable resistance can be used since the resist is not ultimately peeled. Further, the photoresist used in the present embodiment can be a cationic polymerization-type epoxy resin composition in consideration of adhesiveness, mechanical strength, stability against a liquid, and resolution. In particular, the photoresist can be a photocationic polymerization-type epoxy resin composition containing an epoxy resin and a photopolymerization initiator. The epoxy resin can be a bisphenol A-type or F-type epoxy resin, a phenol novolac-type epoxy resin, a cresol novolac-type epoxy resin, or a polyfunctional epoxy resin having an oxycyclohexane skeleton. When the polyfunctional epoxy resin is used, a cured material is three-dimensionally cross-linked and is suitable for obtaining predetermined characteristics. Examples of the epoxy resin include “CELLOXIDE 2021”, “GT-300 series”, “GT-400 series”, and “EHPE3150” (trade names) produced by Daicel Corporation, “jER1031S”, “jER1004”, “jER1007”, “jER1009”, “jER1010”, “jER1256”, and “157S70” (trade names) produced by MITSUBISHI CHEMICAL CORPORATION, “EPICLON N-695”, “EPICLON N-865”, “EPICLON 4050”, and “EPICLON 7050” (trade names) produced by DAINIPPON INK AND CHEMICALS, INCORPORATED, “TECHMORE VG3101” and “EPOX-MKR1710” (trade names) produced by PRINTEC CORPORATION, “DENACOL series” (trade name) produced by Nagase ChemteX Corporation, and “EP-4000S” and “EP-4010S” (trade names) produced by ADEKA Corporation. Two or more types of these photopolymerization initiators may be used in combination. The photopolymerization initiators can be sulfonic acid compounds, diazomethane compounds, sulfonium salt compounds, iodonium salt compounds, and disulfone-based compounds. In addition, the photopolymerization initiator can be a photoacid generating agent. Examples of the photopolymerization agent include “ADEKA OPTOMER-SP-170”, “ADEKA OPTOMER-SP-172”, and “SP-150” (trade names) produced by ADEKA Corporation, “BBI-103” and “BBI-102” (trade names) produced by Midori Kagaku Co., Ltd., “IBPF”, “IBCF”, “TS-01”, and “TS-91” (trade names) produced by SANWA CHEMICAL CO., LTD., “CPI-210”, “CPI-300”, and “CPI-410” (trade names) produced by San-Apro Ltd., and “Irgacure290” (trade name) produced by BASF Japan Ltd. Two or more types of the photopolymerization initiators may be used in combination. To further improve the adhesion performance, polyols or silane coupling agents may be added to each resin composition. Examples of the commercially available silane coupling agent include “A-187” (trade name) produced by Momentive Performance Materials Inc. To improve the pattern resolution or to adjust the sensitivity, the following materials may be added: sensitizers such as anthracene compounds, basic materials such as amines, and acid generating agents which generate weakly acidic (pKa=−1.5 to 3.0) toluenesulfonic acid. Examples of the commercially available acid generating agent which generates toluenesulfonic acid include “TPS-1000” (trade name) produced by Midori Kagaku Co., Ltd. and “WPAG-367” (trade name) produced by Wako Pure Chemical Industries, Ltd. Regarding the photoresist, “SU-8 series” and “KMPR-1000” (trade names) produced by KAYAKU MicroChem Corp., and “TMMR S2000” and “TMMF S2000” (trade names) produced by TOKYO OHKA KOGYO CO., LTD., which are commercially available as negative resists, may also be used.

The photoresponsive material used in the present embodiment can be selected from compounds that absorb light with a wavelength within the range of 400 nm to 500 nm or 200 nm to 400 nm. Further, the photoresponsive material used in the present embodiment can be selected from compounds having maximum fluorescence in a wavelength range of 500 nm to 600 nm or 600 nm to 700 nm. Regarding the photoresponsive material, a compound having a quantum dot and a perovskite-type crystal structure (hereafter abbreviated as perovskite compound) is adopted.

Regarding a material for forming a quantum dot usable in the present embodiment, examples of the compound or element suitable for the material for forming the quantum dot include group II-VI compounds, group III-V compounds, group IV-VI compounds, group IV elements, and group IV compounds and combinations of these.

Examples of the group II-VI compounds include CdSe, CdSeS, CdTe, CdSeTe, CdSTe, ZnSe, ZnSeS, ZnSeTe, ZnS, ZnTe, ZnSTe, ZnO, MgSeMgS, CdZnS, CdZnSe, CdZnTe, MgZnSe, MgZnS, CdZnSeS, CdZnSeTe, and CdZnSTe and mixtures of these.

Examples of the group III-V compounds include InN, InP, InAs, InSb, InNP, InNAs, InNSb, InPAs, InPSb, GaN, GaP, GaAs, GaSb, GaNP, GaNAs, GaNSb, GaPAs, GaPSb, AlN, AIP, AlAs, AlSb, AINP, AINAs, AINSb, AIPAs, AlPSb, GaAINP, GaAINSb, GaAlPAs, GaAlPSb, GaInNP, GaInNSb, GalInPSb, InAINP, InAINSb, and InAlPSb and mixtures of these.

Examples of the group IV-VI compounds include PbS, PbSe, PbTe, PbSeS, PbSeTe, PbSTe, SnSeS, SnSeTe, SnSTe, SnS, SnSe, SnTe, SnPbS, SnPbSe, SnPbTe, SnPbSSe, SnPbSeTe, and SnPbSTe and mixtures of these.

Examples of the group IV elements include Si and Ge, and examples of the group IV compounds include SiC and SiGe and mixtures of these.

To improve the light-emitting quantum yield, the structure of the quantum dot can be a core-shell structure, and in such an instance, the shell material is selected from materials that exhibit a small difference from a core material in the lattice constant.

A perovskite compound has a perovskite-type crystal structure containing A, B, and X as components. There is no particular limitation regarding the perovskite compound containing A, B, and X as components. The structure of the compound may be any of a three-dimensional structure, a two-dimensional structure, and a pseudo-two-dimensional structure. In the instance of a three-dimensional structure, the perovskite compound is denoted by ABX₃, and in the instance of a two-dimensional structure, the perovskite compound is denoted by A₂BX₄.

Specific examples of the perovskite compound having a three-dimensional structure denoted by ABX₃ include CsPbBr₃, CsPbCl₃, CsPbI₃, CsPbBr_{(3-y)}I_{y} (0<y<3), CsPbBr_{(3-y)}Cl_{y} (0<y<3), FAPbBr₃, FAPbCl₃, FAPbI₃, FAPbBr_{(3-y)}I_{y} (0<y<3), FAPbBr_{(3-y)}Cl_{y} (0<y<3) (FA represents formamidinium), MAPbBr₃, MAPbCl₃, MAPbI₃, MAPbBr_{(3-y)}I_{y} (0<y<3), and MAPbBr_{(3-y)}Cl_{y} (0<y<3) (MA represents methylammonium).

Specific examples of the perovskite compound having a two-dimensional structure denoted by A₂BX₄ can include Cs₂PbBr₄, Cs₂PbCl₄, Cs₂Pb₁₄, Cs₂PbBr_{(4-y)}I_{y} (0<y<4), Cs₂PbBr_{(4-y)}Cl_{y} (0<y<4), FA₂PbBr₄, FA₂PbCl₄, FA₂Pb₁₄, FA₂PbBr_{(4-y)}I_{y} (0<y<4), FA₂PbBr_{(4-y)}Cl_{y} (0<y<4) (FA represents formamidinium), MA₂PbBr₄, MA₂PbCl₄, MA₂PbI₄, MA₂PbBr_{(4-y)}I_{y} (0<y<4), and MA₂PbBr_{(4-y)}Cl_{y} (0<y<4) (MA represents methylammonium).

In this regard, a material doped with Eu, Gd, Yb, Mn, Ce, Bi, Sm, Ho, or Tb may be used as the perovskite compound.

In consideration of layer transferability, the thickness of the resist layer is preferably 3 μm or more and 20 μm or less and more preferably 5 μm or more and 14 μm or less.

There is no particular limitation regarding the method for forming the resist layer 2 on the first surface 1 of the film 3. For example, known coating methods such as a spin coating method, a gravure coating method, a bar coating method, an ink jet method, a spraying method, a dipping method, and a die coating method may be used. Of these, using an ink jet method illustrated in FIG. 3B(3b-1) to FIG. 3B(3b-3) enables the resist layer 2 containing a photoresponsive material in a resist to be formed in a predetermined region. In addition, the amount of the resist layer 2 used in the ink jet method is smaller than that in the above-described coating methods. For example, the spin coating method uses a large amount of the resist layer 2 containing a photoresponsive material in a resist. Consequently, when an expensive photosensitive photoresponsive material is used in the present embodiment, the ink jet method can be adopted. In this regard, in the ink jet method, satellites, non-ejection, or variations between ejection nozzles occur. On the other hand, as illustrated in FIG. 3A and FIG. 3B(3b-1) to FIG. 3B(3b-3), after the resist layer 2 is formed, the resist layer 2 containing a photoresponsive material in a resist material may be repeatedly formed a plurality of times until a predetermined thickness is reached in the predetermined region. Consequently, even when satellites, non-ejection, or variations between ejection nozzles occur, the thickness of the resist layer 2 is averaged, and the uniformity is enhanced. When the resist layer 2 is formed on a first surface 1 of the film 3, and thereafter prebake is performed, the strength of the resist layer 2 is improved, and cohesive failure during layer transfer is suppressed from occurring. In this regard, “containing a photoresponsive material in a resist material” in the present embodiment includes the form in which nanoparticles serving as the photoresponsive material are dispersed in a resin serving as the resist material and the form in which such nanoparticles are aggregated in the resist. In addition, the form in which nanoparticles serving as the photoresponsive material are dispersed in a resin serving as the resist material includes the form in which secondary particles, such nanoparticles constituting secondary particles, are dispersed in the resin serving as the resist material.

### Third Step

The third step corresponds to Step S130 in FIG. 1, FIG. 2A, and FIG. 3B(3b-1). In addition, the third step (Step S130) corresponds to FIG. 2B(2b-2) and FIG. 2B(2b-3).

The first surface 4 of a bank substrate 6 provided with partition walls 5 is made to face the first surface 1 of the multilayer film as illustrated in FIG. 2B(2b-2). As illustrated in FIG. 2B(2b-3), the multilayer film and the bank substrate 6 are pressurized together by using a pressure-applying unit 11 arranged on the second surface 7 of the film 3 and a supporting structure, not illustrated in the drawing, arranged on the back surface of the bank substrate 6 on which no partition walls are disposed. As a result, the resist layer 2 is locally pressurized by the partition walls 5 and is pushed into the bank portions 9 surrounded by the bank bottom surface 8 and the partition walls 5. In such an instance, the partition walls 5 may function as spacers so as to maintain a space between the first surface 1 of the film 3 and the bank bottom surface 8 due to contact between the first surface 1 of the film 3 and the upper surfaces of the partition walls 5 or due to pressurization being performed until the resist layer 2 is divided.

The resist layer 2 is layer-transferred to the bank substrate 6 due to the resist layer 2 being peeled off the first surface 1 of the film 3. When the film 3 has lower adhesiveness to the resist than the bank bottom surface and the partition wall, the resist layer is readily layer-transferred to the bank substrate. In addition, since the first surface 4 of the bank substrate has partition walls and thereby has a larger contact area with the resist than the film 3, layer transfer to the bank substrate readily occurs. In this regard, “layer-transferred” in the present specification means that the resist layer 2 is moved from one supporting structure to another supporting structure and may be reworded simply as “moved” or “transferred”.

The bank substrate 6 according to the present embodiment denotes a bank substrate in which the first surface 4 of the bank substrate is provided with the partition walls 5 and is divided by the partition walls into sections corresponding to pixels of a photoresponsive array element. A section surrounded by the partition walls 5 is denoted as a bank, and banks may be arranged in a stripe array or a honeycomb array or a modified array of these.

The density of the banks is preferably 100 ppi or more and more preferably 300 ppi or more.

In the present step, since the partition wall has a structure for segmentation, optical blocking properties such as with a structure called a black matrix between pixels is not limited to being required in the first step to the third step. Such optical blocking properties include reflectance and absorptance.

Regarding the material for forming the partition wall, any one of resins and metals may be used. A material in which a light-transmitting resin contains a light-blocking material such as carbon black may be adopted. In addition, a commercially available black resist may be used, and CFPR BK produced by TOKYO OHKA KOGYO CO., LTD., V-259BKIS produced by NIPPON STEEL Chemical & Material Co., Ltd., CK-7001 produced by FUJIFILM Electronic Materials Co., Ltd., or the like may be used. The reflection density of the partition wall is preferably 3 or more and is more preferably 4.5 or more when utilized for a higher quality display element. In the present embodiment, the surface of the partition wall is not limited to having water repellency and oil repellency. When the surface of the partition wall has water repellency and oil repellency, there is a concern that deterioration in the adhesiveness to the barrier layer formed on the partition wall may be caused and that the reliability of the photoresponsive array element may deteriorate.

The height of the partition wall is determined in accordance with the thickness required of the photoresponsive material layer, and the thickness of the resist layer formed in advance in the first step is adjusted in accordance with the total volume of the banks. The thickness of the resist formed on the film being set to be less than the height of the partition wall enables the resist layer to be placed in the bank without protruding higher than the partition wall. In this regard, in the present embodiment, a resist layer that is not sufficiently placed in the bank may be present on the upper surface of the partition wall after the present step.

Regarding the base material of the bank substrate, glass plates such as quartz glass, borosilicate glass, aluminosilicate glass, and soda-lime glass having a silica coated surface and resin plates such as polycarbonates, polymethyl methacrylates, and polyethylene terephthalates may be used. A metal thin film or another color filter layer, a resin layer, a transistor and a circuit, and the like may be formed on the base material. The base material is a transparent material having a light-transmitting property, and, for example, transparent glass substrates such as quartz glass, PYREX (registered trademark) glass, and synthetic quartz plates and transparent flexible base materials such as transparent resin films and optical resin films may be used. Of these, a glass substrate composed of non-alkaline glass in which no alkaline compound is contained in glass can be used. Specifically, “7059 Glass”, “1737 Glass”, “Eagle 200” (registered trademark), and “Eagle XG” (registered trademark) produced by Corning, “AN 100” produced by ASAHI GLASS CO., LTD., and “OA-10G” and “OA-11” produced by Nippon Electric Glass Co., Ltd. are suitable. These are raw materials having a small thermal expansion coefficient and having excellent dimensional stability and operability in high-temperature heating treatment.

In the present embodiment, the first surface of the substrate is made to face the first surface of the film, and, as illustrated in FIG. 2B(2b-3), the resist layer is layer-transferred to the bank substrate by applying pressure from the second surface of the film by using a pressure-applying unit 11 of the film. The adhesiveness of the bank bottom surface and the partition wall to the photoresist is set to be higher than the adhesiveness of the film, and therefore the resist layer is transferred to the bank substrate. Since the surface of the photoresist before development has high adhesiveness, the photoresist adheres to the bank bottom surface due to contact and is readily peeled off the film. In such an instance, the resist layer is also attached to the partition wall but is then removed in the later step. A roller is used as the pressure-applying unit. Any one of rubber, resin, ceramic, and metal may be used as the base material of the roller, with rubber having flexibility to enable the resist layer to be readily pushed into the bank. In addition, the bank substrate does not readily break in response to pressurization. Heating the roller during pressurization facilitates softening and introduction of the resist layer into the bank. In this regard, adjusting the thickness of the resist layer and the pressurization force of the roller enables the uppermost surface of the resist layer to be indented lower than the uppermost surface of the partition wall. The present step may be performed under a condition of either atmospheric pressure or reduced pressure. When the present step is performed under reduced pressure, a gap is not readily generated between the bank bottom surface and the resist layer. In this regard, other than the present embodiment, each color resist layer in which a photoresponsive material is contained in a photoresist may be patterned into a bank size on the film and may be layer-transferred.

### Fourth Step

The fourth step includes a step of removing a portion of the resist layer 2 moved to the bank portion 9 from the bank substrate and corresponds to Step S140 in FIG. 2A, FIG. 2B(2b-4), and FIG. 2B(2b-5). Step S140 includes Step S144 of exposing a first predetermined region in accordance with the arrangement of the partition wall 5 and Step S146 of developing a second predetermined region in accordance with a history of the exposure step (Step S144). The second predetermined region is in accordance with any one of the first predetermined region and a region out of the first predetermined region depend on which type of a photoresist is used in the exposure step (Step S144), negative or positive.

In the present embodiment, exposure is used as a patterning measure when a photoresist is used as the resist layer 2 prepared in the second step (Step S120). In the second step (Step S120), a resist having sensitivity to another external stimulus is applicable, and in the present step, a patterning technique and a patterning mask in accordance with such sensitivity are applicable. Either a positive resist or a negative resist is applicable to the resist layer 2 prepared in the second step (Step S120).

As illustrated in FIG. 2B(2b-4), the resist layer 2 is exposed and developed, and as illustrated in FIG. 2B(2b-5), an unexposed resist layer is removed. When a negative photoresist is used, a resist layer in which a photoresponsive material is contained in a photoresist in an unexposed portion is removed due to development. Specifically, not only the interior of the other color bank but also the upper surface of the partition wall are made to be unexposed portions. Consequently, since a resist layer remaining on the upper surface of the partition wall is removed, a photoresponsive array element in which color mixing and crosstalk are suppressed from occurring is produced. There is no particular limitation regarding an exposure machine used in the exposure step according to the present embodiment, and known exposure machines may be used. Regarding the exposure light, known exposure machines such as carbon arc lamps, mercury vapor lamps, high-pressure mercury lamps (g-line (436 nm), h-line (405 nm), and i-line (365 nm)), xenon lamps, YAG lasers, Ar ion lasers, semiconductor lasers, F2 excimer lasers (157 nm), ArF excimer lasers (193 nm), and KrF excimer lasers (248 nm) may be used. The exposure light may be appropriately selected in accordance with the photosensitive wavelength of the photoresist to be used. Regarding an exposure apparatus, projection exposure apparatuses having a single wavelength as a light source such as i-line-exposing steppers and KrF steppers and projection exposure apparatuses having a broad wavelength mercury lamp as a light source such as Mask Aligner MPA-600Super (trade name, produced by CANON KABUSHIKI KAISHA) may be used. Post exposure bake (PEB) may be performed in accordance with the photoresist to be used.

Organic solvents may be usable as a developing solution according to the present embodiment. In particular, examples include propylene glycol monomethyl ether acetate (PGMEA), propylene glycol monomethyl ether (PGME), methyl isobutyl ketone (MIBK), diglyme, isopropyl alcohol (IPA), n-butyl acetate, and xylene and liquid mixtures of the above-described solvents such as PGMEA/PGME, MIBK/xylene, and MIBK/PGMEA. In addition, as the situation demands, rinse treatment by using isopropyl alcohol (IPA) or post bake may be performed. Since the quantum dot and the perovskite compound in the photoresponsive material according to the present embodiment are readily decomposed by water, use of the developing solution including tetramethylammonium hydroxide (TMAH) can be avoided. The thickness of the resist layer in the bank may be controlled by increasing the development time. Subsequently, with respect to the other color bank, a resist layer that exhibits the other color fluorescence is subjected to the first step to the third step. As a result, a photoresponsive array element 13 is produced.

### Modified Form of First Embodiment

A modified form of the first embodiment will be described with reference to FIG. 2C and FIG. 2D. A manufacturing method 1500 of the photoresponsive array element according to the present embodiment corresponds to a flow chart 1500 illustrated in FIG. 2C and is a form in which, in addition to the manufacturing method 1000 of the photoresponsive array element according to the first embodiment, another photoresponsive array element is separately transferred. The present embodiment includes a fifth step (Step S150) of preparing a second multilayer film in which a second resist layer supporting a second photoresponsive material that differs in photoresponsivity from the photoresponsive material prepared in the second step, and a second film supporting the second resist layer are stacked. The present embodiment further includes a sixth step (Step S160) of bringing the second multilayer film into contact with the bank substrate from which a portion of the resist layer 2 is removed and thereafter moving the second film away from the bank substrate 6.

The fifth step (Step S150) and the sixth step (Step S160) according to the present embodiment are performed in conformity with the second step (Step S120) and the third step (Step S130) according to the first embodiment. As in the first embodiment, the manufacturing method 1500 of the photoresponsive array element according to the present embodiment may involve a step of removing a portion of the second resist layer, which corresponds to the fourth step and which is not illustrated in the drawing.

The manufacturing method 1500 of the photoresponsive array element according to the present embodiment differs from the manufacturing method 1000 of the photoresponsive array element according to the first embodiment in that the fifth step (Step S150) and the sixth step (Step S160) are further included. According to the present embodiment, as illustrated in FIG. 2D, a photoresponsive array element in which the photoresponsive materials are separately transferred is provided.

### Second Embodiment

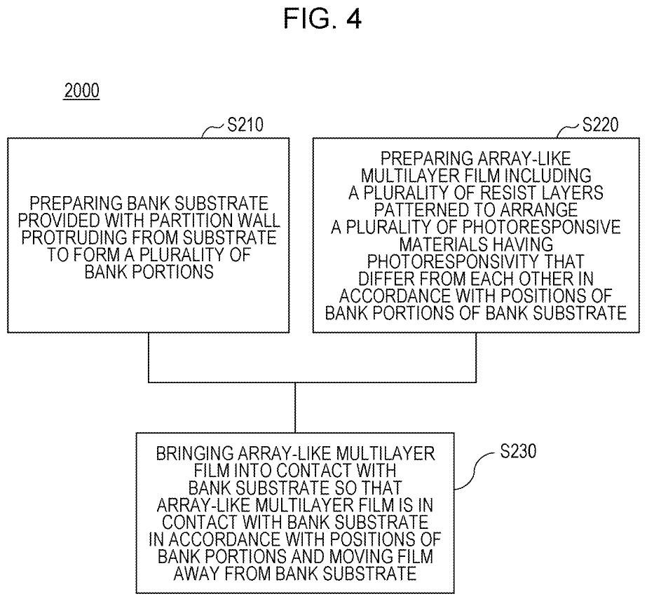

A manufacturing method 2000 of the photoresponsive array element according to the present embodiment will be described with reference to the flow chart illustrated in FIG. 4.

The manufacturing method 2000 according to the present embodiment includes Step S210 of preparing a bank substrate provided with a partition wall protruding from a substrate to form a plurality of bank portions as illustrated in FIG. 4. Step S210 of preparing a bank substrate according to the present embodiment corresponds to Step S110 of preparing a bank substrate according to the first embodiment. Step S210 may be reworded as a seventh step in the present specification.

The manufacturing method 2000 according to the present embodiment includes Step S220 of preparing an array-like multilayer film including a plurality of resist layers patterned to arrange a plurality of photoresponsive materials having photoresponsivity that differ from each other in accordance with the positions of the bank portions 9 of the bank substrate 6. Step S220 of preparing an array-like multilayer film according to the present embodiment corresponds to Step S120 of preparing a multilayer film according to the first embodiment but differs from Step S120 in the point that resist layers containing different photoresponsive materials are separately applied.

The manufacturing method 2000 according to the present embodiment includes Step S230 of bringing the array-like multilayer film into contact with the bank substrate 6 so that the array-like multilayer film is in contact with the bank substrate 6 in accordance with the positions of the bank portions 9 and thereafter moving the film away from the bank substrate 6. The film moved away from the bank substrate 6 is a support film, not illustrated in the drawing, for supporting the array-like multilayer film.

Step S230 of moving the film away from the bank substrate 6 according to the present embodiment corresponds to Step S130 of bringing the multilayer film into contact with the bank substrate and thereafter moving the film away from the bank substrate according to the first embodiment.

Step S210 is reworded as a step of performing the second step (Step S120) so as to preparing an array-like multilayer film including a plurality of resist layers patterned to arrange a plurality of photoresponsive materials having photoresponsivity that differ from each other in accordance with the positions of the bank portions 9 of the bank substrate 6.

Likewise, Step S220 is reworded as a step of performing the third step so as to bring the array-like multilayer film into contact with the bank substrate 6 in accordance with the positions of the bank portions 9.

### EXAMPLES

### Example 1

In the present example, the embodiment is used, and specific example of the method for manufacturing a photoresponsive array element according to the embodiment will be described with reference to FIG. 3A, FIG. 3B(3b-1) to 3B(3b-3), FIG. 2A, and FIG. 2B(2b-1) to 2B(2b-5).

TMMF resist (produced by TOKYO OHKA KOGYO CO., LTD.) was used as a photoresist composed of epoxy resin. InP/ZnSeS having the maximum peak wavelength of the emission spectrum of the quantum dot of 530 nm was used as a photoresponsive material and was dispersed in TMMF resist at a concentration of 30% by weight. Further, titanium oxide particles having an average particle diameter of 0.23 μm were dispersed at 3.5% by weight, and the resulting resist was used as the resist 2 containing the photoresponsive material in the photoresist. The resist 2 containing the photoresponsive material in the photoresist was formed using an ink jet system, and Materials Printer DMP-2850 produced by FUJIFILM Corporation was used. Lumirror S10 (produced by Toray Industries, Ltd.) composed of PET having a thickness of 76 μm to 125 μm was used as the film 3, and as illustrated in FIG. 3B(3b-1) to 3B(3b-3), the resist layer 2 was repeatedly formed 8 times by using an ink jet system in a region of 180×180 mm on the first surface 1 of the film (FIG. 3A).

The thickness of the resist layer 2 containing the photoresponsive material in the photoresist was set to be 7.5 μm due to prebake at 80° C. for 1 min (FIG. 2B(2b-1)).

A bank substrate having the following specification was used.
Substrate: non-alkaline glass
Substrate size: 200×200 mm
Substrate thickness: 0.6 mm
Partition-forming region: 180×180 mm
Bank portion: 280×80 (μm) rectangular non-light-blocking portions with corners having R of 5 μm arranged at a shorter-side-pitch of 100 μm and a longer-side-pitch of 300 μm
Partition wall: width of 20 μm, height of 10 μm, partition portion reflection density of 3

The bank substrate 6 was set in a roll-type laminator (VTM-200 produced by Takatori Corporation), and lamination was performed under reduced pressure of 100 Pa, at a stage temperature and a roller temperature of 40° C., a roller pressure from the second surface 7 of the film of 0.4 MPa, and a roller speed of 10 mms (FIG. 2B(2b-3)). Consequently, the resist layer 2 was brought into contact with the partition wall 5 of the bank substrate 6, and the resist layer 2 was introduced in the bank portion 9. The resist layer 2 was layer-transferred to the bank substrate 6 by the film 3 being peeled off (FIG. 2B(2b-3)). A portion of the resist layer was attached and remained on the upper surface of the partition wall 5. A photomask 12 was aligned and arranged so that a bank and a partition wall which had longer sides adjoining each other were set to be unexposed portions, exposure was performed in an amount of exposure of 400 mJ/cm² (FIG. 2B(2b-4)), and PEB was performed at 80° C. Propylene glycol 1-monomethyl ether 2-acetate was used as a developing solution, and the resist layer in the unexposed portion was removed. In such an instance, the resist layer on the upper surface of the partition wall was also removed. The height of the partition wall was 10 μm, whereas the resist layer 2 in the bank portion 9 exhibited favorable uniformity, and the thickness up to the uppermost surface was 9.9 μm. Regarding the resulting photoresponsive array element 13, when the light having a maximum peak wavelength of 445 nm from a blue light emitting diode was passed through the bank filled with the resist layer 2, green fluorescence was emitted (FIG. 2B(2b-5)).

### Example 2

In the present example, the photoresponsive array element produced in Example 1 was used as the bank substrate.

A bank adjacent to the bank filled in Example 1 was filled in the manner akin to the manner in Example 1 except that InP/ZnSeS having the maximum peak wavelength of the emission spectrum of the quantum dot of 640 nm was used as the photoresponsive material (FIG. 2D). Regarding the resulting photoresponsive array element, when the light from a blue light emitting diode was passed through, green fluorescence and red fluorescence were emitted, and color mixing and crosstalk were not recognized.

### Example 3

The present example was performed in the manner akin to the manner in Example 1 except that a perovskite compound CsPbBr₃ covered with polysilazane having the maximum peak wavelength of 535 nm was used as the photoresponsive material. Regarding the resulting photoresponsive array element, when the light having a maximum peak wavelength of 445 nm from a blue light emitting diode was passed through the bank filled with the resist layer as in Example 1, green fluorescence was emitted.

### Example 4

In the present example, regarding a bank substrate used, a portion of banks were filled with a photosensitive material layer that was the resist layer containing the photoresponsive material in the photoresist used in Example 1 from which the photoresponsive material was removed. The resist layer which exhibited green fluorescence was introduced in the bank as in Example 1, and the resist layer which exhibited red fluorescence was introduced in the bank as in Example 2. Regarding the resulting photoresponsive array element, when the light from a blue light emitting diode was passed through, blue fluorescence, green fluorescence, and red fluorescence were emitted from different banks.

### Example 5

The present example was performed in the manner akin to the manner in Example 1 except that the resist layer containing the photoresponsive material in the photoresist was formed on the first surface of the film by a spin coating method. Regarding the resulting photoresponsive array element, when the light from a blue light emitting diode was passed through the bank filled with the resist layer as in Example 1, green fluorescence was emitted.

### Comparative Example 1

The bank substrate used in Example 1 was used. The resist layer was introduced by ejecting the resist layer containing the photoresponsive material in the photoresist directly into the bank.

The resist layer got on the partition wall and flew into the adjacent bank. Further, landing of satellites in the adjacent bank was observed.

The method for manufacturing a photoresponsive array element described in the present specification includes a first configuration to a tenth configuration.

A first configuration includes a method for manufacturing a photoresponsive array element including a first step of preparing a bank substrate provided with a partition wall protruding from a substrate to form a plurality of bank portions, a second step of preparing a multilayer film including a resist layer containing a photoresponsive material and a resist material supporting the photoresponsive material and a film supporting the resist layer, and a third step of bringing the multilayer film into contact with the bank substrate to apply pressure from the partition wall to the resist layer and thereafter moving the film away from the bank substrate.

A second configuration includes the method for manufacturing a photoresponsive array element according to the first configuration, wherein the third step is performed so that at least a portion of the resist layer is moved from the multilayer film to at least a portion of the plurality of bank portions.

A third configuration includes the method for manufacturing a photoresponsive array element according to the first configuration or the second configuration further including, after the third step, a fourth step of removing a portion of the resist layer moved to the bank portions.

A fourth configuration includes the method for manufacturing a photoresponsive array element according to the third configuration, wherein the resist material contains a photoresist, and the fourth step includes performing an exposure step of exposing a predetermined region in accordance with the arrangement of the partition wall and a development step of developing the predetermined region in accordance with a history of the exposure step.

A fifth configuration includes the method for manufacturing a photoresponsive array element according to the third configuration or the fourth configuration further including, after the fourth step, a fifth step of preparing a second multilayer film in which a second resist layer supporting a second photoresponsive material that differs from the photoresponsive material in photoresponsivity and a second multilayer film supporting the second resist layer are stacked, and a sixth step of bringing the second multilayer film into contact with the bank substrate from which a portion of the resist layer is removed and thereafter moving the second film away from the bank substrate.

A sixth configuration includes the method for manufacturing a photoresponsive array element according to the first configuration or the second configuration, wherein the second step is performed so that an array-like multilayer film including a plurality of resist layers patterned to arrange a plurality of photoresponsive materials having photoresponsivity that differ from each other in accordance with the positions of the bank portions of the bank substrate is prepared, and the third step is performed so that the array-like multilayer film is in contact with the bank substrate in accordance with the positions of the bank portions.

A seventh configuration includes the method for manufacturing a photoresponsive array element according to any one of the first configuration to the sixth configuration, wherein the second step is performed so that the resist layer is formed on the film by using an ink jet system.

An eighth configuration includes the method for manufacturing a photoresponsive array element according to the first configuration or the second configuration, wherein a thickness of the resist layer is less than a height of the partition wall from the substrate in the second step.

A ninth configuration includes the method for manufacturing a photoresponsive array element according to the first configuration or the second configuration, wherein the third step includes a step of pressurizing the resist layer so that the thickness of the resist layer is set to be less than the height of the partition wall from the substrate.

A tenth configuration includes the method for manufacturing a photoresponsive array element according to the third configuration or the fourth configuration, wherein the fourth step includes a step of removing a portion of the resist layer so that a thickness of the resist layer moved to the bank portion is set to be less than a height of the partition wall from the substrate.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-190926, filed Nov. 30, 2022 which is hereby incorporated by reference herein in its entirety.

What is claimed is:

1. A method for manufacturing a photoresponsive array element comprising:
a first step of preparing a bank substrate provided with a partition wall protruding from a substrate to form a plurality of bank portions;
a second step of preparing a multilayer film including a resist layer containing a photoresponsive material and a resist material supporting the photoresponsive material and a film supporting the resist layer; and
a third step of bringing the multilayer film into contact with the bank substrate to apply pressure from the partition wall to the resist layer and thereafter moving the film away from the bank substrate.

2. The method for manufacturing a photoresponsive array element according to claim 1,
wherein the third step is performed so that at least a portion of the resist layer is moved from the multilayer film to at least a portion of the plurality of bank portions.

3. The method for manufacturing a photoresponsive array element according to claim 1 further comprising, after the third step,
a fourth step of removing a portion of the resist layer moved to the bank portions.

4. The method for manufacturing a photoresponsive array element according to claim 3,
wherein the resist material contains a photoresist, and
the fourth step includes performing an exposure step of exposing a predetermined region in accordance with the arrangement of the partition wall and a development step of developing the predetermined region in accordance with a history of the exposure step.

5. The method for manufacturing a photoresponsive array element according to claim 3 further comprising, after the fourth step:
a fifth step of preparing a second multilayer film in which a second resist layer supporting a second photoresponsive material that differs in photoresponsivity from the photoresponsive material, and a second multilayer film supporting the second resist layer are stacked; and
a sixth step of bringing the second multilayer film into contact with the bank substrate from which a portion of the resist layer is removed and thereafter moving the second film away from the bank substrate.

6. The method for manufacturing a photoresponsive array element according to claim 1,
wherein the second step is performed so that an array-like multilayer film including a plurality of resist layers patterned to arrange a plurality of photoresponsive materials having photoresponsivity that differ from each other in accordance with the positions of the bank portions of the bank substrate is prepared, and
the third step is performed so that the array-like multilayer film is in contact with the bank substrate in accordance with the positions of the bank portions.

7. The method for manufacturing a photoresponsive array element according to claim 1,
wherein the second step is performed so that the resist layer is formed on the film by using an ink jet system.

8. The method for manufacturing a photoresponsive array element according to claim 1,
wherein a thickness of the resist layer is less than a height of the partition wall from the substrate in the second step.

9. The method for manufacturing a photoresponsive array element according to claim 1,
wherein the third step includes a step of pressurizing the resist layer so that the thickness of the resist layer is set to be less than the height of the partition wall from the substrate.

10. The method for manufacturing a photoresponsive array element according to claim 3,
wherein the fourth step includes a step of removing a portion of the resist layer so that a thickness of the resist layer moved to the bank portion is set to be less than a height of the partition wall from the substrate.
